(19) United States
(12) Patent Application Publication
(10) Pub. No.: US 2009/0001488 A1
(43) Pub. Date: Jan. 1, 2009

(54) Cantilever with integral probe tip

(76) Inventors: John Magana, San Jose, CA (US); Brett Huff, Fremont, CA (US)

Correspondence Address: CAVEN & AGHEVLI;c/o INTELLEVATE, LLC, P.O. BOX 52050, MINNEAPOLIS, MN, 55402, US

(21) Appl. No.: 11/824,509

(22) Filed: Jun. 29, 2007

(51) Int. Cl. H01L 27/14; H01L 21/02

(52) U.S. Cl. 257/428; 438/57; 257/E27.122; 257/E21.002

(57) ABSTRACT

In one embodiment, a metallic micro-cantilever, comprises a silicon substrate, at least one via plug extending from a surface of the silicon substrate, a metallic layer cantilevered from the at least one via plug, and a metallic probe tip extending from a surface of the metallic layer.

### BACKGROUND

The subject matter described herein relates generally to semiconductor processing, and to micro-electronic machines (MEMS).

MEMS tip/cantilever assemblies are typically fabricated using single crystal silicon substrates (SOI) or poly crystalline thin films on Silicon and variations of standard front-end CMOS processing technologies such as oxidation, diffusion, and thermal Silicon Nitride growth. Because of the high temperatures inherent in typical front-end processing, it is not currently possible to easily integrate the fabrication of MEMS cantilevers into the backend of a conventional CMOS process technology.

### BRIEF DESCRIPTION OF THE DRAWINGS

The disclosed embodiments will be better understood from a reading of the following detailed description, taken in conjunction with the accompanying Figures in the drawings in which:

FIG. 1 is a schematic illustration of a metallic micro-cantilever with an integral probe-tip, according to embodiments of the invention.

FIG. 2 is a flowchart illustrating a method of making a metallic micro-cantilever with an integral probe-tip, according to embodiments of the invention.

FIGS. 3A-3N are cross-sectional views of the metallic micro-cantilever with an integral probe-tip of FIG. 1 at different points in its manufacturing process, according to embodiments of the invention.

For simplicity and clarity of illustration, the drawing Figures illustrate the general manner of construction, and descriptions and details of well-known features and techniques may be omitted to avoid unnecessarily obscuring the discussion of the described embodiments of the invention. Additionally, elements in the drawing Figures are not necessarily drawn to scale. For example, the dimensions of some of the elements in the Figures may be exaggerated relative to other elements to help improve understanding of embodiments of the present invention. The same reference numerals in different Figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used.

### DETAILED DESCRIPTION

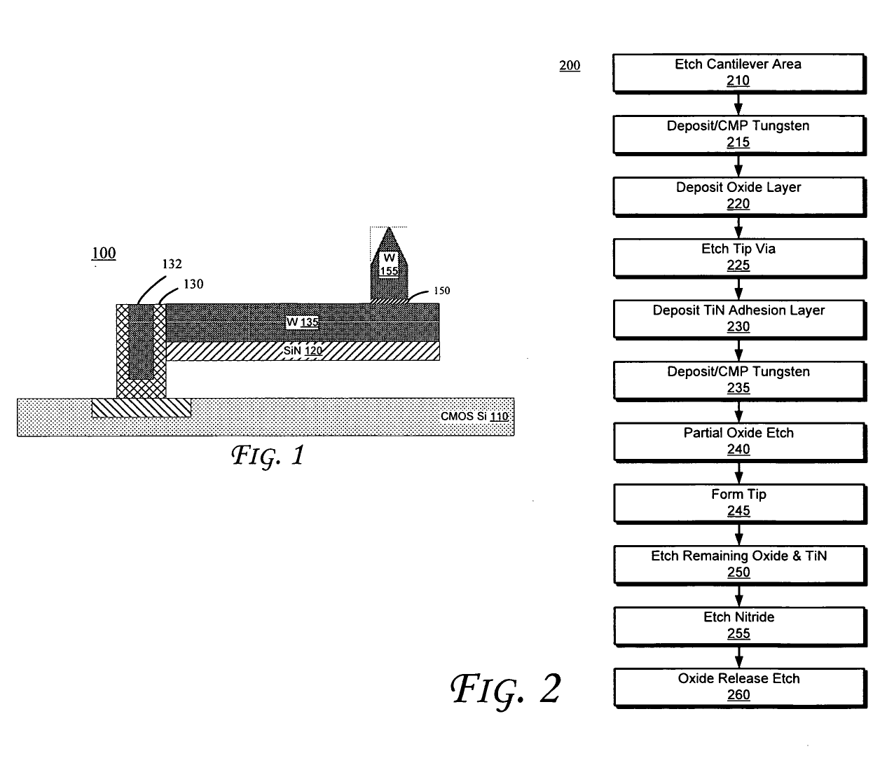

FIG. 1 is a schematic illustration of a metallic micro-cantilever with an integral probe-tip according to an embodiment of the invention. In the embodiment depicted in FIG. 1, cantilever assembly 100 comprises a base 110 formed from a complementary metal-oxide-semiconductor (CMOS) substrate material such as, e.g., a CMOS silicon. Substrate 110 may comprise one or more active semiconductor elements such as, e.g., sense amplifiers, or passive elements such as, e.g., resistors, capacitors, diodes, etc. In addition, the substrate 110 may comprise at least one power and signal routing layer, and in some embodiments may comprise multiple power and signal routing layers.

Cantilever assembly 100 further comprises a tungsten (W) or other suitable metallic or alloy cantilever element 135 supported by one or more via plugs 130. In some embodiments, via plug 130 comprises a conductive core 132 which provides as an electrical connection to one or more semiconductor devices on the underlying substrate 110. N. B. Tungsten was only cited as an example metal for the cantilever . . . the claim is that other metals with suitable mechanical or electrical properties could be utilized as well. For example, many other commonly available metals such as Platinum or Iridium could be employed. Similarly, alloy systems could be used as well. Essentially, the claim is that any easily deposited metal or alloy (i.e., via CVD, PECVD, electroplating, etc.) could be used.

Tungsten cantilever 135 extends laterally from plug(s) 130 and comprises a probe-tip element 155 extending from the surface of the cantilever 155. In the embodiment depicted in FIG. 1, a titanium-nitride (TiN) adhesion layer is disposed between the probe-tip element 155 and the surface of tungsten cantilever 135. In the embodiment depicted in FIG. 1, a layer of silicon-nitride (SiN) is disposed on the surface of tungsten cantilever 135 opposite from the probe-tip element 155.

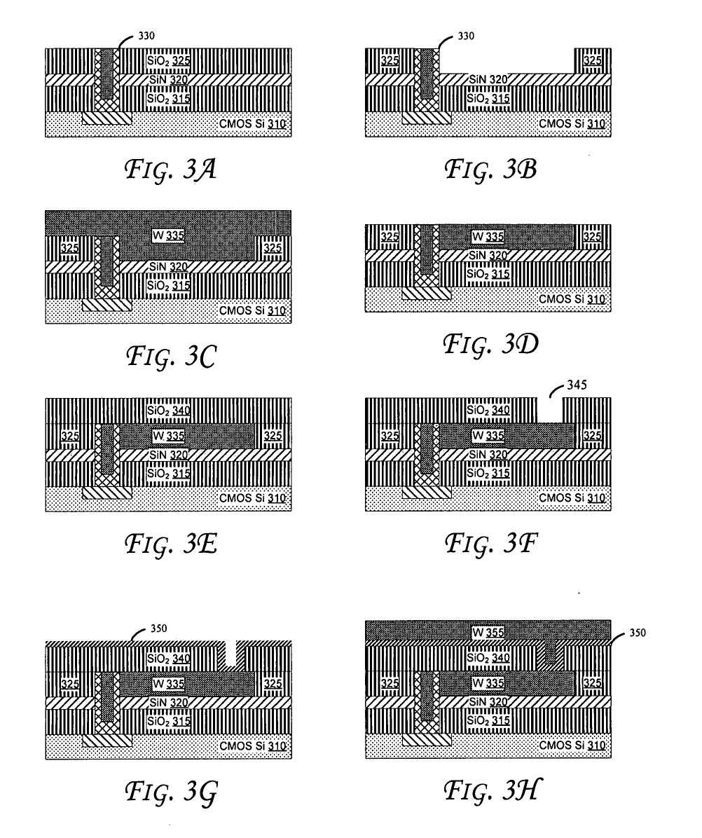

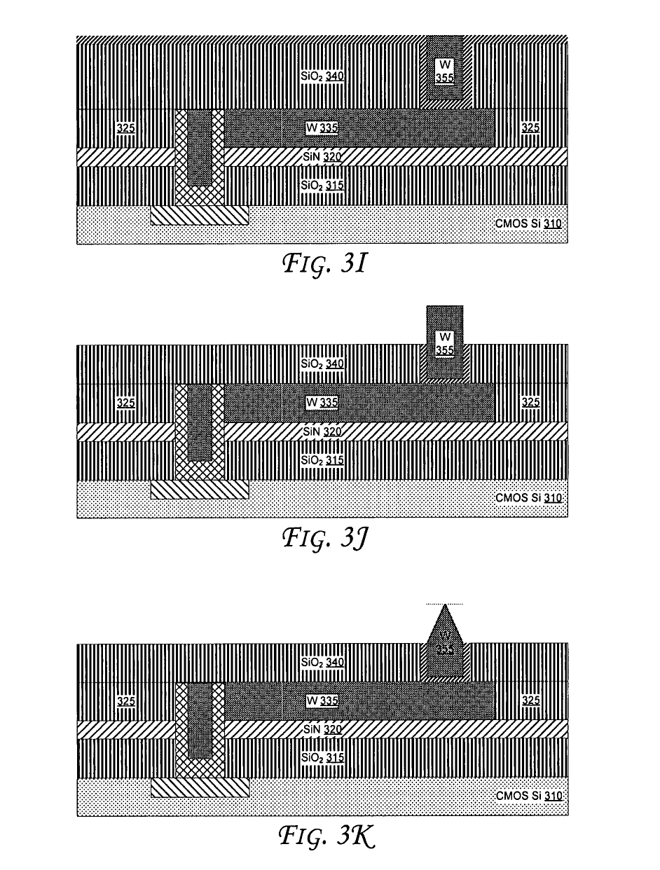

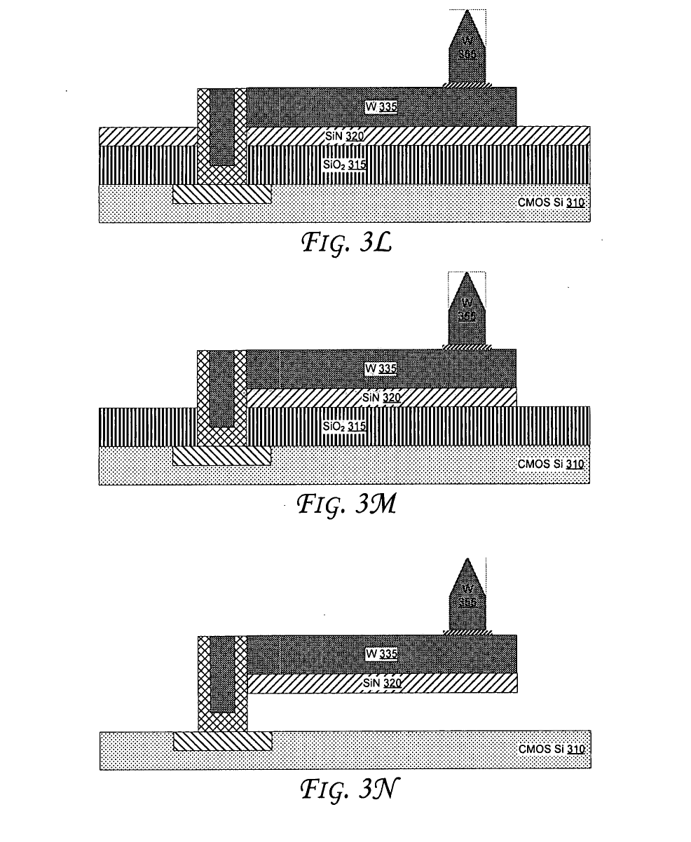

A method of making a metallic micro-cantilever, such as the cantilever assembly 100 depicted in FIG. 1, will be explained with reference to FIGS. 2 and 3A-3N. FIG. 2 is a flowchart illustrating a method of making a metallic micro-cantilever with an integral probe-tip, according to embodiments of the invention. FIGS. 3A-3N are cross-sectional views of the metallic micro-cantilever with an integral probe-tip of FIG. 1 at different points in its manufacturing process, according to embodiments of the invention.

Referring to FIG. 3A, in one embodiment the method begins with a completed CMOS assembly 300 post via chemical-mechanical polishing (CMP). In the embodiment depicted in FIG. 3A, the assembly 300 comprises a CMOS silicon substrate 310, a silicon dioxide (SiO₂) layer 315 disposed on the substrate 310, a silicon-nitride (SiN) layer 320 disposed on the silicon dioxide layer 320, and a silicon dioxide (SiO₂) layer 325 disposed on the silicon nitride layer 320. A via plug 330 is embedded in the structure as illustrated in FIG. 1. In the embodiment depicted in FIG. 1, the cantilever is anchored/electrically connected directly to the CMOS Silicon device below by means of a conventional (e.g., salicide) contact. However, it is be possible to integrate a plurality of signal and power routing layers onto the CMOS silicon substrate prior to inclusion of the following cantilever processing steps.

At operation 210 the silicon dioxide layer 325 is removed from a portion of the cantilever area, resulting in the structure depicted in FIG. 3B. In some embodiments the etch process exposes the via plug 330. Also, in some embodiments the SiN layer functions as a etch stop

At operation 215 a layer of tungsten is deposited onto the assembly 100 (FIG. 3C) and a CMP process is implemented to remove excess tungsten, resulting in the structure depicted in FIG. 3D. Although tungsten is used in the embodiment depicted in FIG. 3, other metals (e.g., titanium, aluminum and aluminum alloys, copper, etc.) or semiconductors could be substituted. In some embodiments the deposited tungsten may be subject to a stress control operation to impart uniform mechanical properties of the cantilevers across the wafer.

At operation 220 a layer 340 of silicon dioxide is deposited on the structure 300, resulting in the structure depicted in FIG. 3E. At operation 225 a via 345 is etched in the silicon dioxide layer 340, e.g., using conventional lithographic etching techniques, resulting in the structure depicted in FIG. 3F. In the embodiment depicted in FIG. 3F, the tungsten layer 335 serves as an etch stop.

At operation 230 a titanium-nitride (TiN) adhesion layer 350 is deposited on the assembly 300 and subjected to a CMP process, resulting in the structure depicted in FIG. 3G At operation 240, a layer 355 of tungsten is deposited on the TiN layer 350, resulting in the structure depicted in FIG. 3H, and is subjected to a CMP process, resulting in the structure depicted in FIG. 3I. Note that the via hole is filled with tungsten.

At operation 245 a etch process is implanted to remove the TiN layer 350 and a portion of the silicon dioxide layer 340, which reveals the tungsten core 355 of in the via, resulting in the structure depicted in FIG. 3J. At operation 250 the tungsten core 355 is shaped into a probe-tip, resulting in the structure depicted in FIG. 3K. In some embodiments an isotropic etch, electrochemical etching or other physical processing may be used to sharpen the tip. Other techniques which could be employed to sharpen the tip include, but are not limited to, iterative chemical or thermal oxidation followed by dilute chemical etching to progressively sharpen the apex, and high bias inert gas sputter etching (e.g., etches at ˜4:1 etch rate etching of ˜45 degree surfaces with respect to normal surfaces).

At operation 250 the remaining silicon dioxide layer 340 and the titanium nitride 350 on the side of the probe tip via are etched, resulting in the structure depicted in FIG. 3L. Note that the silicon nitride layer 320 may be used as an etch stop. At operation 255 a nitride etch is performed to remove silicon nitride layer 320, resulting in the structure depicted in FIG. 3M. At operation 260 an oxide release etch is performed, which removes the layer of silicon dioxide 315, resulting in the structure depicted in FIG. 3N, which corresponds to the structure depicted in FIG. 1.

Thus, the techniques described herein enable the integration of conductive cantilevers onto a CMOS backplane post transistor processing (i.e., in the device back-end). This enables VLSI circuitry to be placed in close physical proximity to the cantilever/tip assembly, thereby enabling high-level integration of elements such as sense amplifiers, micro heaters, drive circuits, etc. This is particularly useful in devices which are constructed by lamination of multiple layers. Examples of such devices include nano-scale switches, optical devices and so-called seek and scan probe-based memories. Such devices benefit from the ability to place additional circuitry on the same silicon assembly as the mechanical element. For example, structures necessary for tapping mode operation of a seek and scan probe device could be located on the same silicon assembly as the mechanical element.

In addition, fabricating cantilever type elements from metallic materials provides improvements in resistance-capacitance parasitic delays typically associated with relatively high resistance elements of state of the art cantilevers fabricated from highly doped single crystal silicon or polycrystalline silicon. Further, metallic cantilevers have exhibit high visible light reflectivity that may be sufficient for laser detection surfaces in typical AFM detection schemes. This may eliminate the need for additionally reflective coatings and the associated engineering to ensure that the intrinsic stress of the reflective film is compatible with the desired total stress/load of the cantilever element.

In addition, metallic cantilever have much better thermal conductivity than those fabricated from silicon. Higher thermal conductivity is desirable for certain applications such as rapid heating or quenching as may be required in the write, read, erase of data bits on a chalcogenide media. Further, the methods enable a plurality of signal and power routing layers to be placed under the cantilever assembly, which simplifies power and signal input/output routing for read, write, erase, positioning, etc.

In the description and claims, the terms coupled and connected, along with their derivatives, may be used. In particular embodiments, connected may be used to indicate that two or more elements are in direct physical or electrical contact with each other. Coupled may mean that two or more elements are in direct physical or electrical contact. However, coupled may also mean that two or more elements may not be in direct contact with each other, but yet may still cooperate or interact with each other.

Reference in the specification to “one embodiment” “some embodiments” or “an embodiment” means that a particular feature, structure, or characteristic described in connection with the embodiment is included in at least an implementation. The appearances of the phrase “in one embodiment” in various places in the specification may or may not be all referring to the same embodiment.

Although embodiments have been described in language specific to structural features and/or methodological acts, it is to be understood that claimed subject matter may not be limited to the specific features or acts described. Rather, the specific features and acts are disclosed as sample forms of implementing the claimed subject matter.

What is claimed is:

1. A method of forming a metallic micro-cantilever with an integral probe-tip, the method comprising:
removing a portion of a first oxide layer of a semiconductor assembly;
filling the removed portion of the first oxide layer with a first layer of metallic material;
applying a second oxide layer to the first layer of metallic material;
forming a probe via in the second oxide layer;
applying a titanium nitride layer to the second oxide layer;
filling the probe via with a second layer of metallic material;
removing the second oxide layer to expose the second layer of metallic material;
forming a probe tip on the second layer of metallic material; and
removing at least a layer of oxide material to form a cantilever structure.

2. The method of claim 1, wherein filling the removed portion of the first oxide layer with a first layer of metallic material comprises:
applying a layer of metallic material over the first oxide layer; and
implementing a chemical mechanical polishing operation on the layer of metallic material.

3. The method of claim 1, wherein forming a probe via in the second oxide layer comprises a lithographic etching process.

4. The method of claim 3, wherein applying a titanium nitride layer to the second oxide layer comprises a chemical vapor deposition process.

5. The method of claim 3, wherein applying a titanium nitride layer to the second oxide layer comprises applying a titanium nitride layer in the probe via.

6. The method of claim 1, wherein filling the probe via with a second layer of metallic material comprises:
applying a layer of metallic material over the first oxide layer; and
implementing a chemical mechanical polishing operation on the layer of metallic material depositing a layer comprising the first metal.

7. The method of claim 1, wherein removing the second oxide layer to expose the second layer of metallic material comprises removing a portion of the titanium nitride layer.

8. The method of claim 1, wherein forming a probe tip on the second layer of metallic material comprises implementing at least one of:
an isotropic etch process;
an electrochemical etch process; or
a physical machining process.

9. The method of claim 1, wherein removing at least a layer of oxide material to form a cantilever structure comprises removing an underlying layer of oxide material.

10. The method of claim 1, wherein removing at least layer of oxide material to form a cantilever structure comprises removing the second layer of oxide material.

11. A metallic micro-cantilever, comprising:
a silicon substrate;
at least one via plug extending from a surface of the silicon substrate;
a metallic layer cantilevered from the at least one via plug; and
a metallic probe tip extending from a surface of the metallic layer.

12. The metallic micro-cantilever of claim 11, further comprising a silicon nitride layer disposed adjacent the metallic layer.

13. The metallic micro-cantilever of claim 11, further comprising a titanium nitride later disposed between the metallic layer and the metallic probe tip.

14. The metallic micro-cantilever of claim 11, wherein the via plug comprises a conductive core which provides as an electrical connection to one or more semiconductor devices on the underlying substrate.

15. The method of claim 1, wherein the cantilever structure is formed after one or more transistors are formed on the substrate.
